(19) United States
(12) Patent Application Publication
(10) Pub. No.: US 2025/0353289 A1
(43) Pub. Date: Nov. 20, 2025

(54) TRANSPORT UNIT AND LAMINATION SYSTEM FOR DISPLAY DEVICE INCLUDING THE SAME

(71) Applicant: Samsung Display Co., LTD., Yongin-si (KR)

(72) Inventors: YUNMIN KIM, Yongin-si (KR); SUKJU KANG, Yongin-si (KR); SANG CHEOL KIM, Yongin-si (KR); MYUNG-HUN OH, Yongin-si (KR); Junryeol OH, Yongin-si (KR); DONGGUL LEE, Yongin-si (KR); JUN-HEE LEE, Yongin-si (KR)

(21) Appl. No.: 19/088,475

(22) Filed: Mar. 24, 2025

(30) Foreign Application Priority Data
May 14, 2024 (KR) 10-2024-0063306

(51) Int. Cl. B32B 38/18; B65G 47/91; H01L 21/677; H10K 71/50

(52) U.S. Cl. CPC B32B 38/1841; B32B 38/1858; B65G 47/917; H01L 21/67715; H01L 21/67745; B32B 2457/206; B65G 2201/022; H10K 71/50

(57) ABSTRACT

A transport unit includes a carrier for carrying a first material and a second material, which are loaded thereon, and a docking station detachably combined with the carrier and for supplying an air or power to the carrier to form a vacuum state and to provide a suction force to the carrier. The carrier includes a first stage on which the first material is loaded, a second stage on which the second material is loaded, which faces the first stage, a connection module combined between the first stage and the second stage to rotate the first and second stages with respect to a rotation axis between the first stage and the second stage, and a check valve combined with the connection module to maintain the vacuum state after connection between the docking station and the carrier is released.

This application claims priority to Korean Patent Application No. 10-2024-0063306, filed on May 14, 2024, and all the benefits accruing therefrom under 35 U.S.C. § 119, the content of which in its entirety is herein incorporated by reference.

### BACKGROUND

### 1. Field

The present disclosure relates to a transport unit and a lamination system for a display device including the same. More particularly, the present disclosure relates to a transport unit including a carrier and a lamination system for a display device including the transport unit.

### 2. Description of Related Art

In general, a cover window is attached to a front surface of a display panel to protect the display panel. In this case, an adhesive is provided between the display panel and the cover window to attach the display panel and the cover window.

Researches are conducted on a lamination apparatus to efficiently perform a process of attaching the display panel and the cover window and a manufacturing method of a display device using the lamination apparatus.

### SUMMARY

The present disclosure provides a transport unit that prevents an adhesive surface from being exposed to fallen foreign substances after peeling off of a material and shortens a process time by integrating an input stage and a discharge stage utilizing a carrier, which includes two rotatable stages.

The present disclosure provides a lamination system capable of reducing a process time using two circular material handling systems.

Embodiments of the invention provide a transport unit including a carrier for carrying a first material and a second material, which are loaded thereon, and a docking station detachably combined with the carrier and for supplying an air or power to the carrier to form a vacuum state and to provide a suction force to the carrier. The carrier includes a first stage on which the first material is loaded, a second stage provided with the second material loaded thereon and for facing the first stage, a connection module combined between the first and second stages to rotate the first stage and the second stage with respect to a rotation axis between the first stage and the second stage, and a check valve disposed in the connection module to maintain the vacuum state after connection between the docking station and the carrier is released.

The transport unit may further include a connection module combined between the check value and the first and second stages, the connection module transmits the vacuum state to the first and second stages, and the first and second stages may suction-hold the first and second materials, respectively.

The carrier may include a first operation mode in which the first stage faces upward and the second stage faces downward, a second operation mode in which the first stage faces downward and the second stage faces upward, and a third operation mode in which the first and second stages face a horizontal direction.

The connection module may include a position control part for controlling relative positions between the docking station and the carrier and a rotation part combined with the first and second stages to rotate the first and second stages.

The rotation part may operate in a rotation mode in which the rotation part rotates when the docking station supplies the air and in a fixed mode in which the rotation part does not rotate when the docking station stops supplying the air.

The rotation part may include a rotation housing combined with the first and second stages, a fixing end having a shape corresponding to the rotation housing to be inserted into and combined with the rotation housing, and a one-way cylinder combined with the fixing end to allow the fixing end to reciprocate in one direction.

The rotation part may include a first fixing member, a second fixing member opposite to the first fixing member and combined with the first fixing member by a spring, and a rotation housing provided with a fixing groove defined therein to accommodate the first and second fixing members. The rotation part may rotate when a distance between the first fixing member and the second fixing member decreases by the docking station.

The docking station may include a power supply part for supplying the power to the carrier and a cylinder for supplying the air to the carrier.

Each of the first material and the second material may be at least one of a window and a display panel.

Embodiments of the invention provide a lamination system including a first line along which at least one first carrier provided with a first material loaded thereon reciprocates in a first direction, a second line along which at least one second carrier provided with a second material loaded thereon reciprocates in the first direction, a chamber in which the first material is laminated to the second material, a first supply unit for supplying the first material to the chamber, and a second supply unit for supplying the second material to the chamber. The first line includes a first-first line for moving only in the first direction, a first-second line for moving only in a direction opposite to the first direction, and a first lift for reciprocating between the first-first line and the first-second line.

The second line may include a second-first line for moving only in the first direction, a second-second line for moving only in the direction opposite to the first direction, and a second lift for reciprocating between the second-first line and the second-second line.

The chamber may be disposed between the first line and the second line.

The first-first line and the first-second line may be arranged to face each other in an up-and-down direction crossing the first direction.

The first-first line and the first-second line may be arranged to face each other in a horizontal direction crossing the first direction.

The first carrier may include a first stage on which the first material is loaded, a second stage opposite to the first stage, a connection module combined between the first stage and the second stage to rotate the first and second stages with respect to a rotation axis between the first stage and the second stage, and a check valve disposed in the connection module to maintain a vacuum state.

The lamination system may further include a first loading module for loading the first material in the first carrier and a second loading module for loading the second material in the second carrier.

The lamination system may further include a multi-joint robot to peel off a protective film of the first material.

The first carrier may include two stages facing each other and being rotatable, and the stages may rotate to be perpendicular to an up-and-down direction when the protective film is peeled off.

The first carrier may include two stages facing each other and being rotatable, and a stage on which the peeled-off first material is loaded among the two stages may rotate to face a downward direction while moving to the chamber after the protective film is peeled off.

The first carrier may include two stages facing each other and being rotatable, and a laminate obtained by laminating the first material to the second material may be loaded on one stage among the two stages while moving in the first direction.

According to the above, the transport unit includes the carrier provided with the first stage and the second stage, which are rotatable, and thus, the material to be input and the material to be discharged are able to be transported using one carrier. In addition, since the stages are rotated to allow the peeled off material to face the ground, the peeled off material is prevented from being contaminated by fallen foreign substances. Further, the number of transfers of the material is reduced and thus, a total process time is effectively shortened.

According to the above, the lamination system shortens the process time by utilizing the first line and the second line, which are able to reciprocate in one direction, to eliminate the need to return to reload the next material onto the carrier.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a perspective view of a display device according to an embodiment of the present disclosure;

FIG. 2 is an exploded perspective view of a display device according to an embodiment of the present disclosure;

FIG. 3 is a cross-sectional view of a display module according to an embodiment of the present disclosure;

FIG. 4 is a perspective view of a transport unit according to an embodiment of the present disclosure;

FIG. 5 is a perspective view of a carrier according to an embodiment of the present disclosure;

FIG. 6 is a perspective view of an area AA′ of FIG. 5 according to an embodiment of the present disclosure;

FIG. 7 is a perspective view of a docking station according to an embodiment of the present disclosure;

FIGS. 8A to 8E are front views illustrating an operation of a transport unit according to an embodiment of the present disclosure;

FIGS. 9A to 9D are side views of a carrier according to an embodiment of the present disclosure;

FIGS. 10A to 10D are side views of a carrier according to an embodiment of the present disclosure;

FIG. 11 is a plan view of a lamination system according to an embodiment of the present disclosure;

FIGS. 12A to 12G are side views of an operation of a first line according to an embodiment of the present disclosure; and

FIG. 13 is a plan view of a lamination system according to another embodiment of the present disclosure.

### DETAILED DESCRIPTION

In the present disclosure, it will be understood that when an element (or area, layer, or portion) is referred to as being “on”, “connected to” or “combined with” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms “first”, “second”, “first-first”, “first-second”, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

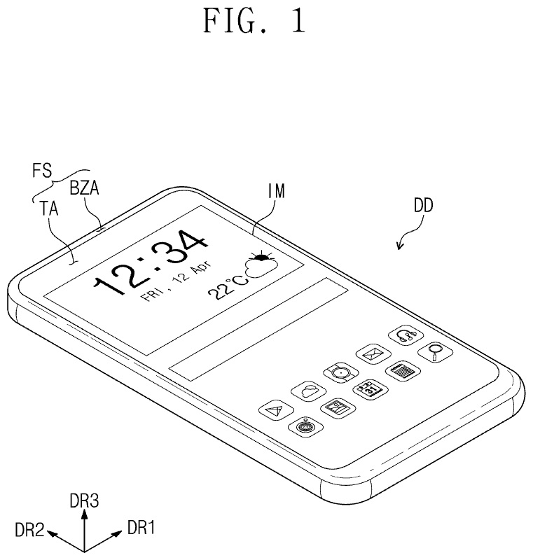

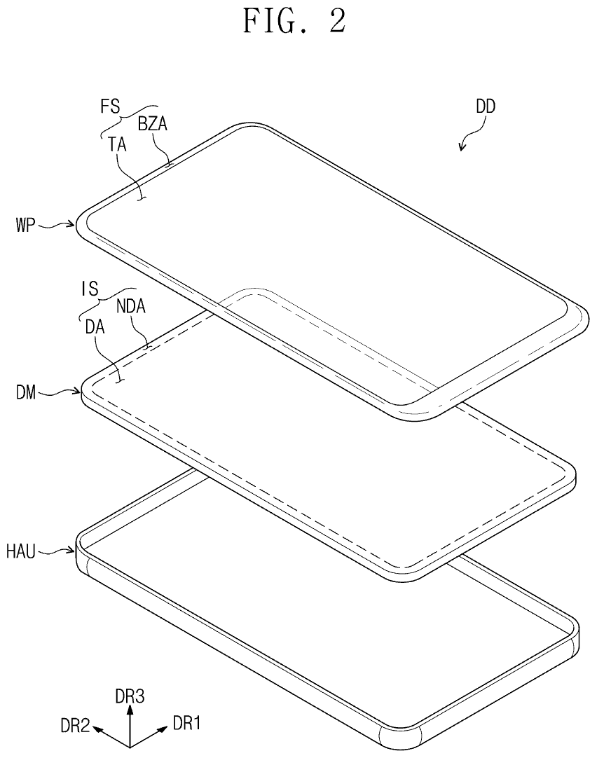

FIG. 1 is a perspective view of a display device according to an embodiment of the present disclosure. FIG. 2 is an exploded perspective view of the display device according to an embodiment of the present disclosure.

The display device DD may be applied to a large-sized electronic item, such as a television set, a monitor, or an outdoor billboard. In addition, the display device DD may be applied to a small and medium-sized electronic item, such as a personal computer, a notebook computer, a personal digital assistant, a car navigation unit, a game unit, a smartphone, a tablet computer, and a camera. However, these are merely examples, and the display device DD may be employed in other display devices as long as they do not deviate from the concept of the present disclosure. In the present embodiment, the smartphone will be described as a representative example of the display device DD.

Referring to FIGS. 1 and 2, the display device DD may display an image IM through a display surface FS, which is substantially parallel to each of a first direction DR1 and a second direction DR2, toward a third direction DR3. The third direction DR3 may be a normal line direction of a plane defined by the first direction DR1 and the second direction DR2. The image IM may include a video and a still image. FIG. 1 shows a clock widget and application icons as a representative example of the image IM. The display surface FS through which the image IM is displayed may correspond to a front surface of the display device DD.

In the present embodiment, front (or upper) and rear (or lower) surfaces of each member of the display device DD may be defined with respect to a direction in which the image IM is displayed. The front and rear surfaces may be opposite to each other in the third direction DR3, and a normal line direction of each of the front and rear surfaces may be substantially parallel to the third direction DR3. The directions indicated by the first, second, and third directions DR1, DR2, and DR3 may be relative to each other, and thus, the directions indicated by the first, second, and third directions DR1, DR2, and DR3 may be changed to other directions. In the following descriptions, the expression “when viewed in a plane” means a state of being viewed in the third direction DR3.

The display device DD may include a window WP, a display module DM, and a housing HAU. The window WP and the housing HAU may be combined with each other to provide an exterior of the display device DD.

The window WP may include an optically transparent insulating material. For example, the window WP may include a glass or plastic material. A front surface of the window WP may define the display surface FS of the display device DD. The display surface FS may include a transmissive area TA and a bezel area BZA. The transmissive area TA may be an optically transparent area. For example, the transmissive area TA may be an area having a visible light transmittance of about 90% or more.

The bezel area BZA may be an area having a relatively lower transmittance than that of the transmissive area TA. The bezel area BZA may define a shape of the transmissive area TA. The bezel area BZA may be disposed adjacent to the transmissive area TA and may surround the transmissive area TA. However, this is merely one example, and the bezel area BZA may be omitted from the window WP according to the embodiment of the present disclosure. The window WP may include at least one functional layer of an anti-fingerprint layer, a hard coating layer, and an anti-reflective layer and should not be particularly limited.

The display module DM may be disposed under the window WP. The display module DM may have a configuration that substantially generates the image IM. The image IM generated by the display module DM may be displayed through a display surface IS of the display module DM and may be viewed by a user through the transmissive area TA.

The display module DM may include a display area DA and a non-display area NDA. The display area DA may be activated in response to electrical signals. The non-display area NDA may be adjacent to the display area DA. The non-display area NDA may surround the display area DA. The non-display area NDA may be covered by the bezel area BZA and may not be viewed from the outside.

The housing HAU may be combined with the window WP. The housing HAU and the window WP combined with the housing HAU may provide an inner space. The display module DM may be accommodated in the inner space.

The housing HAU may include a material with a relatively high rigidity. For example, the housing HAU may include a glass, plastic, or metal material or a plurality of frames and/or plates of combinations thereof. The housing HAU may stably protect the components of the display device DD accommodated in the inner space from external impacts.

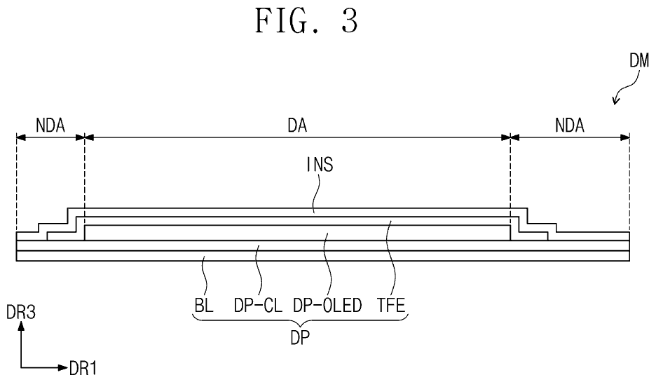

FIG. 3 is a cross-sectional view of the display module DM according to an embodiment of the present disclosure.

Referring to FIG. 3, the display module DM may include a display panel DP and an input sensor INS. Although not shown in figures, the display device DD (refer to FIG. 1) may further include a protective member disposed on a lower surface of the display panel DP or an anti-reflective member and/or a window member disposed on an upper surface of the input sensor INS.

The display panel DP may be a light emitting type display panel, however, it should not be particularly limited. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as the display panel DP.

The display panel DP may include a base layer BL, a circuit element layer DP-CL, a display element layer DP-OLED, and a thin film encapsulation layer TFE. The circuit element layer DP-CL, the display element layer DP-OLED, and the thin film encapsulation layer TFE may be disposed on the base layer BL. The input sensor INS may be disposed directly on the thin film encapsulation layer TFE. In the present disclosure, the expression “A component A is disposed directly on a component B.” means that no adhesive layers are present between the component A and the component B.

The base layer BL may include at least one plastic film. The base layer BL may be a flexible substrate and may include a plastic substrate, a glass substrate, a metal substrate, or an organic/inorganic composite material substrate. In the present disclosure, the display area DA and the non-display area NDA described with reference to FIG. 1B may be defined in the base layer BL of FIG. 3.

The circuit element layer DP-CL may include at least one insulating layer and a circuit element. The insulating layer may include at least one inorganic layer and at least one organic layer. The circuit element may include signal lines and a pixel driving circuit.

The display element layer DP-OLED may include a barrier wall and a light emitting element. The light emitting element may include an anode, an intermediate layer, and a cathode.

The thin film encapsulation layer TFE may include a plurality of thin layers. Some thin layers may be disposed to improve an optical efficiency, and some thin layers may be disposed to protect organic light emitting diodes.

The input sensor INS may obtain coordinate information of an external input. The input sensor INS may have a multi-layer structure. The input sensor INS may include a conductive layer having a single-layer or multi-layer structure. The input sensor INS may include an insulating layer having a single-layer or multi-layer structure. The input sensor INS may sense the external input by a capacitive method. However, the operation method of the input sensor INS should not be particularly limited. The input sensor INS may sense the external input by an electromagnetic induction method or a pressure sensing method. According to an embodiment, the input sensor INS may be omitted.

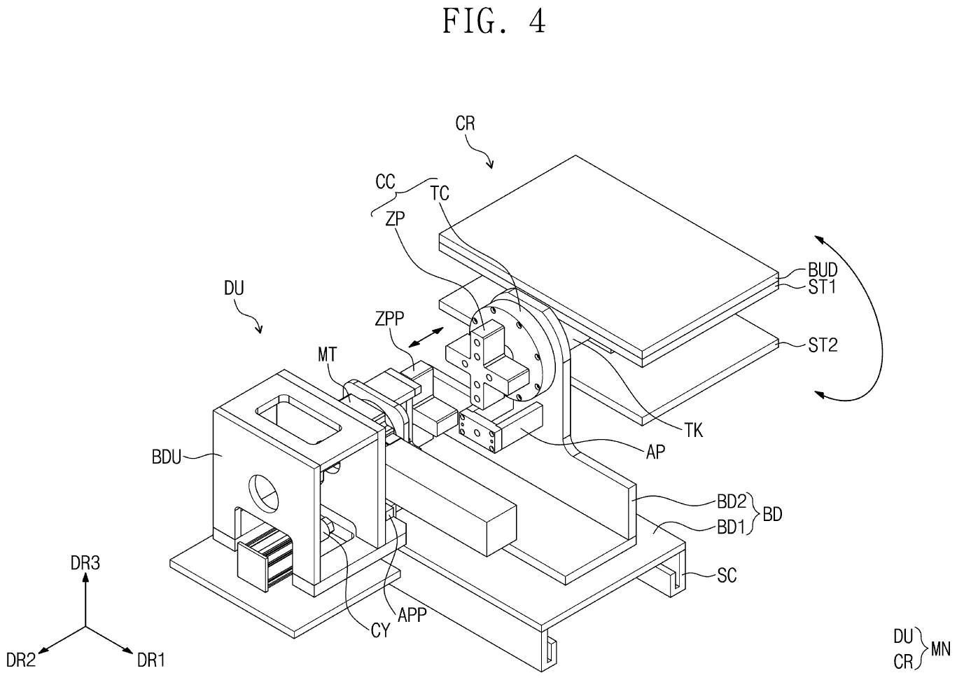

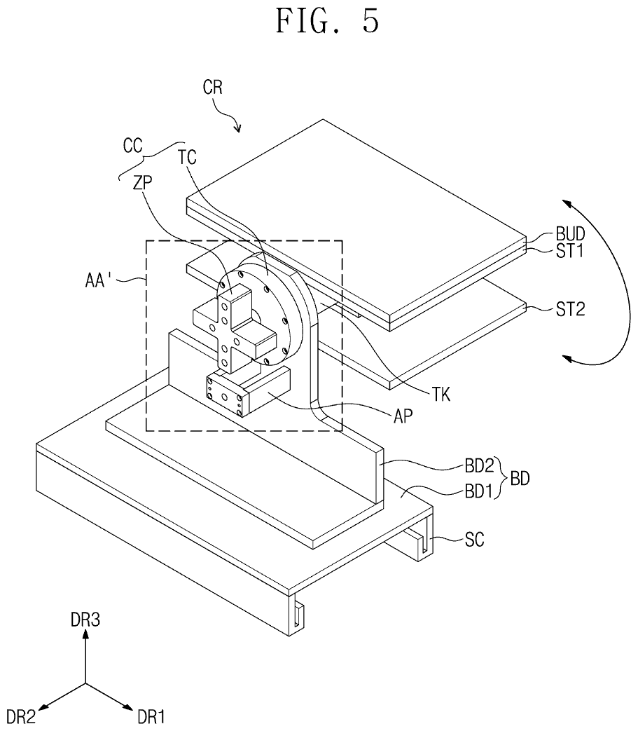

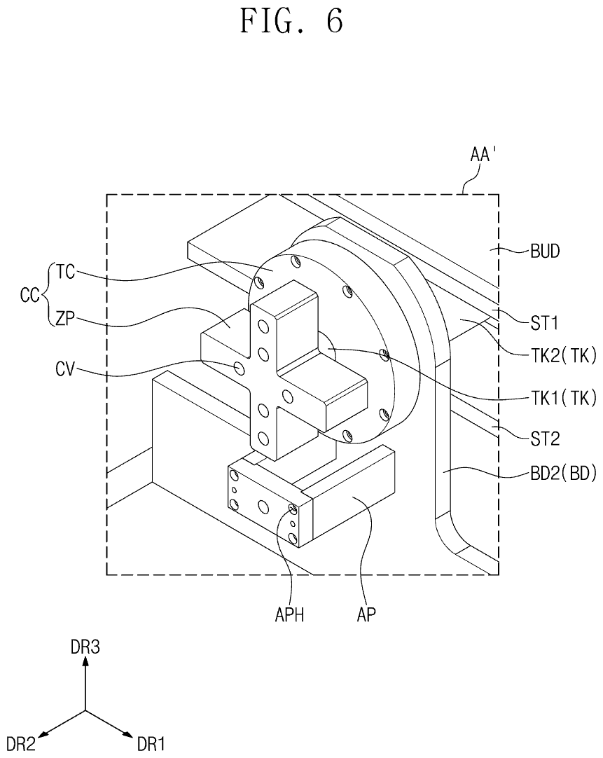

FIG. 4 is a perspective view of a transport unit according to an embodiment of the present disclosure. FIG. 5 is a perspective view of a carrier CR according to an embodiment of the present disclosure. FIG. 6 is a perspective view of an area AA′ of FIG. 5 according to an embodiment of the present disclosure.

Referring to FIGS. 4 to 6, the transport unit MN may include the carrier CR and a docking station DU. The carrier CR may load and transport a first material and a second material. In the present embodiment, the first material may indicate materials loaded on a first stage ST1, and the second material may indicate materials loaded on a second stage ST2.

Each of the first material and the second material may be at least one of the window WP (refer to FIG. 2) and the display panel DP (refer to FIG. 3).

The carrier CR may include a body BD, a first stage ST1, a second stage ST2, a connection module CC, an air inlet part AP, a check valve CV, and a connection module TK. However, components of the carrier CR should not be limited thereto or thereby and may include various general-purpose components.

The body BD may be combined with the first stage ST1 and the second stage ST2 of the carrier CR and may hold the first stage ST1 and the second stage ST2. The body BD may be formed of a sufficiently durable material to prevent changes in position or deformation in shape when the first stage ST1 and the second stage ST2 rotate.

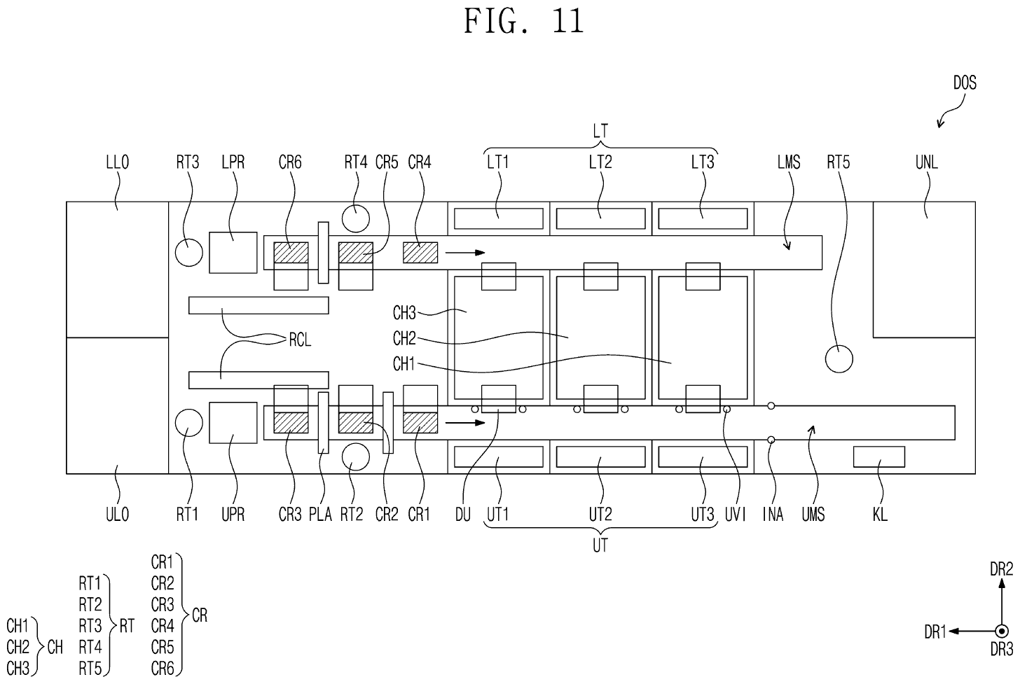

The body BD may include a first body BD1 and a second body BD2. The first body BD1 may have a shape parallel to the plane defined by the first direction DR1 and the second direction DR2, and a rail part SC may be combined with a lower portion of the first body BD1. The rail part SC may be combined with a first line UMS (refer to FIG. 11) and a second line LMS (refer to FIG. 11) and may slide in the first direction DR1. The second body BD2 may extend from the first body BD1 to the third direction DR3 and may be combined with the connection module CC. However, the shape of the body BD should not be limited to the shape of the body BD shown in FIG. 4 and may be changed in various ways.

The first stage ST1 may have a shape substantially parallel to the plane defined by the first direction DR1 and the second direction DR2. The first material having a plane shape may be loaded on the first stage ST1. A fixing part may be combined with the first stage ST1 to fix the first material to the first stage ST1. The first stage ST1 may fix the first material thereto using a suction force provided by the docking station DU and maintained by the check valve CV.

The second stage ST2 may have a shape substantially parallel to the plane defined by the first direction DR1 and the second direction DR2. The second material having a plane shape may be loaded on the second stage ST2. The second stage ST2 may face the first stage ST1 in the third direction DR3. A fixing part may be combined with the second stage ST2 to fix the second material to the second stage ST2. The second stage ST2 may fix the second material thereto using the suction force provided by the docking station DU and maintained by the check valve CV.

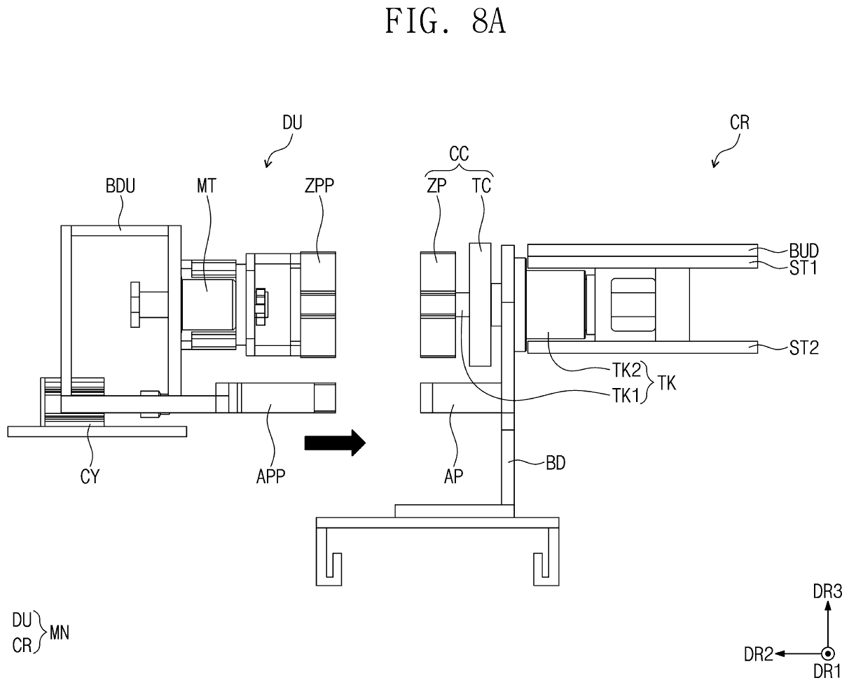

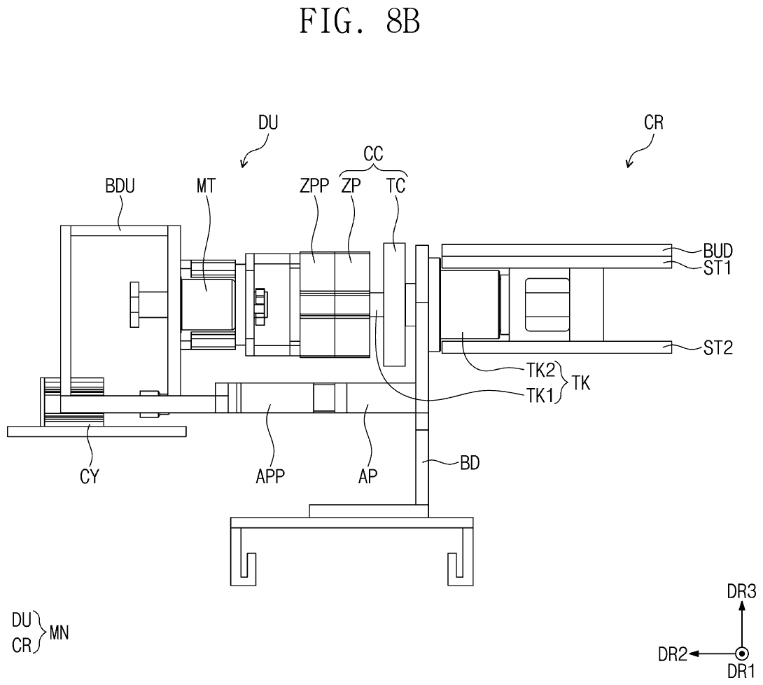

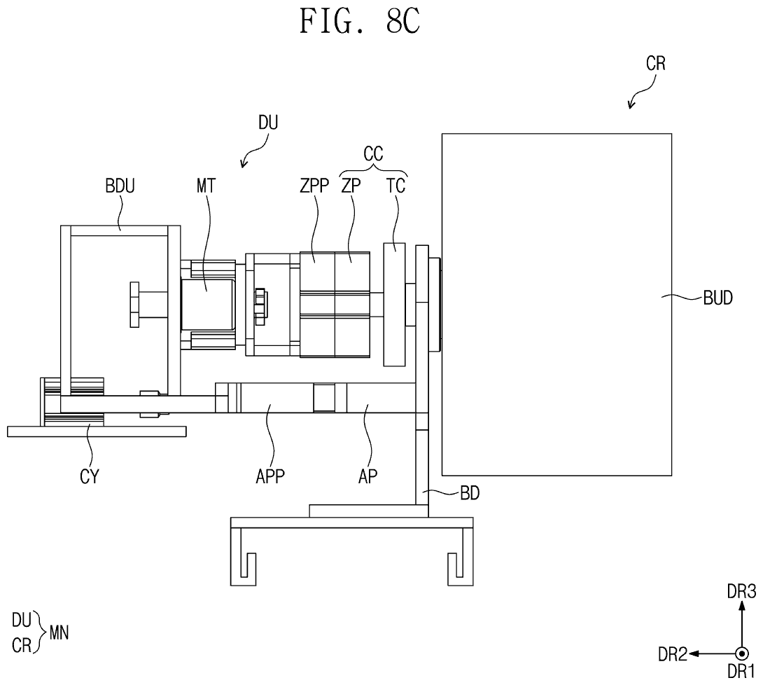

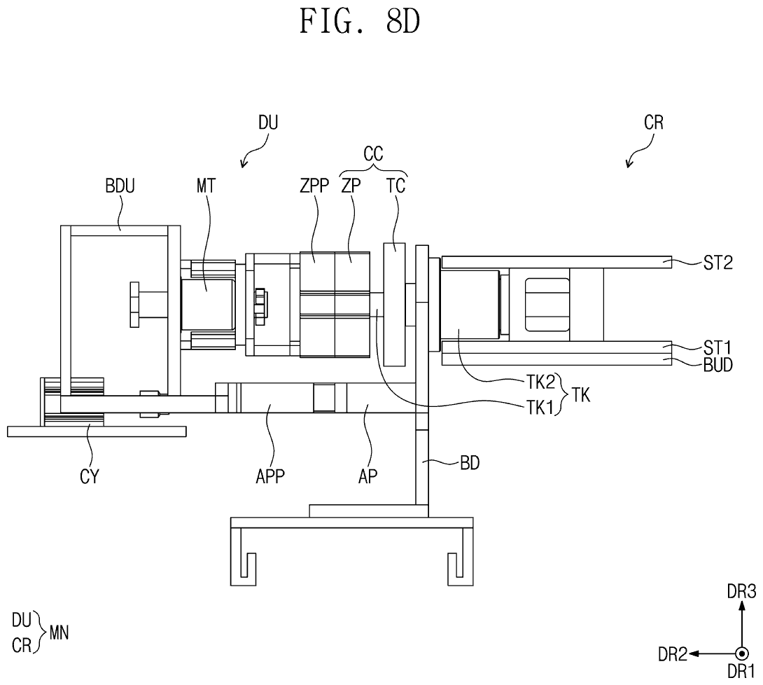

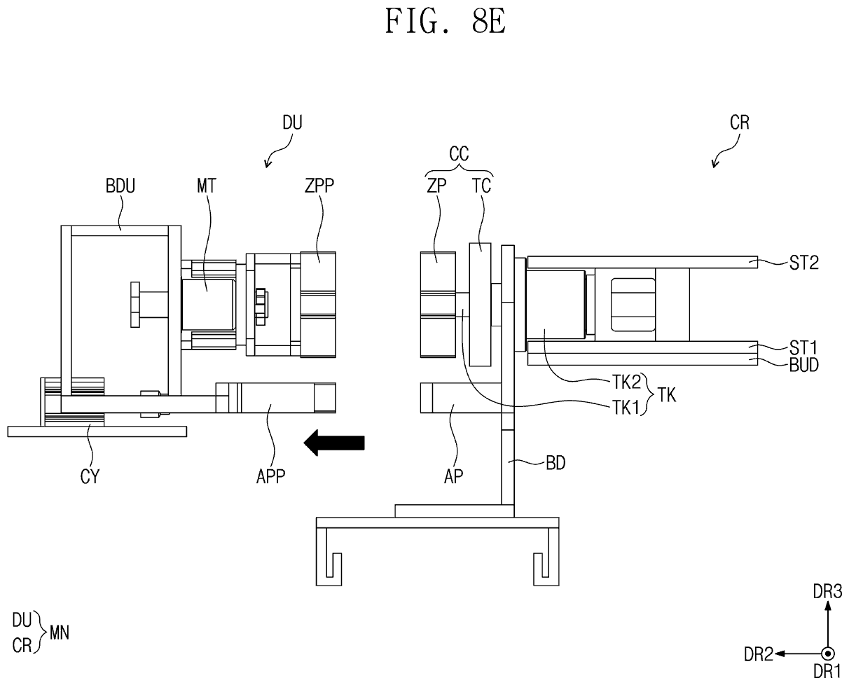

The first stage ST1 and the second stage ST2 may rotate with respect to the second direction DR2 as its rotation axis. That is, the first stage ST1 and the second stage ST2 may be rotated to be in a first operation mode, a second operation mode, and a third operation mode. The first operation mode is a state in which the first stage ST1 faces upward and the second stage ST2 faces downward (refer to FIG. 8B). The second operation mode is a state in which the first stage ST1 faces downward and the second stage ST2 faces upward (refer to FIG. 8D). The third operation mode is a state in which the first stage ST1 and the second stage ST2 are parallel to the plane defined by the second and third directions DR2 and DR3 (refer to FIG. 8C).

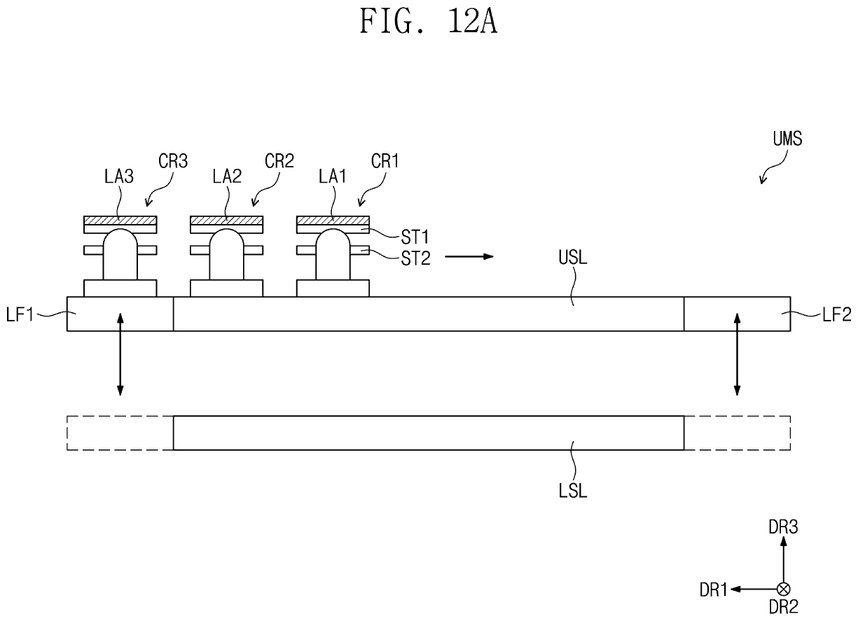

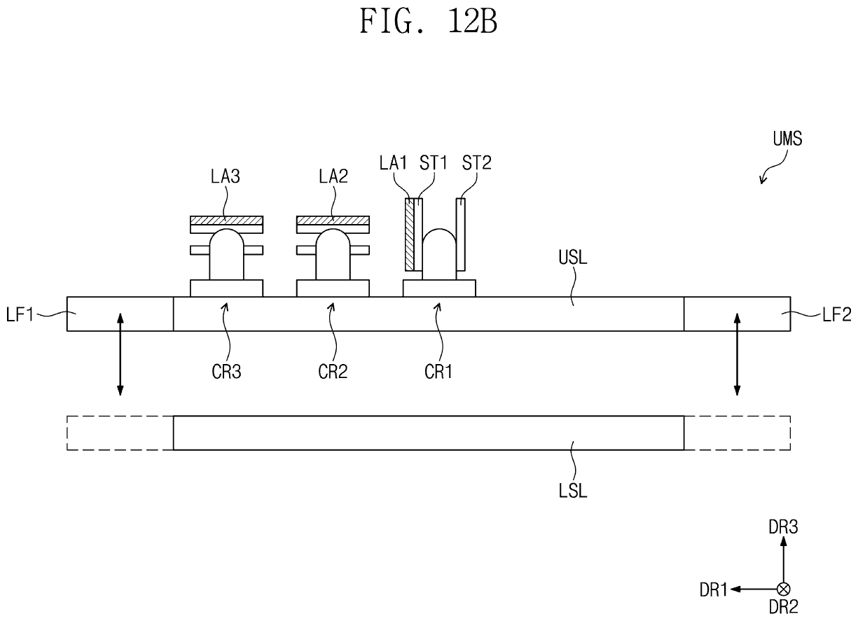

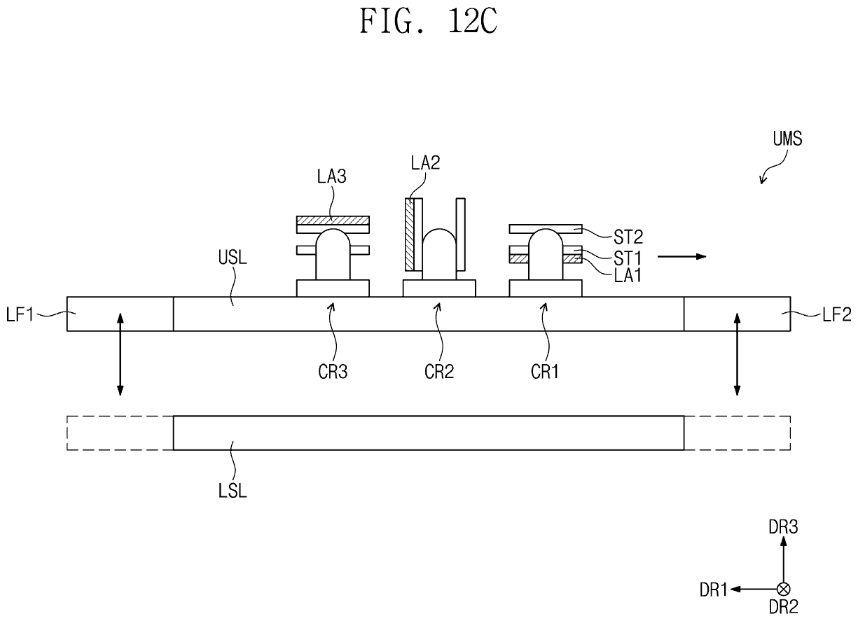

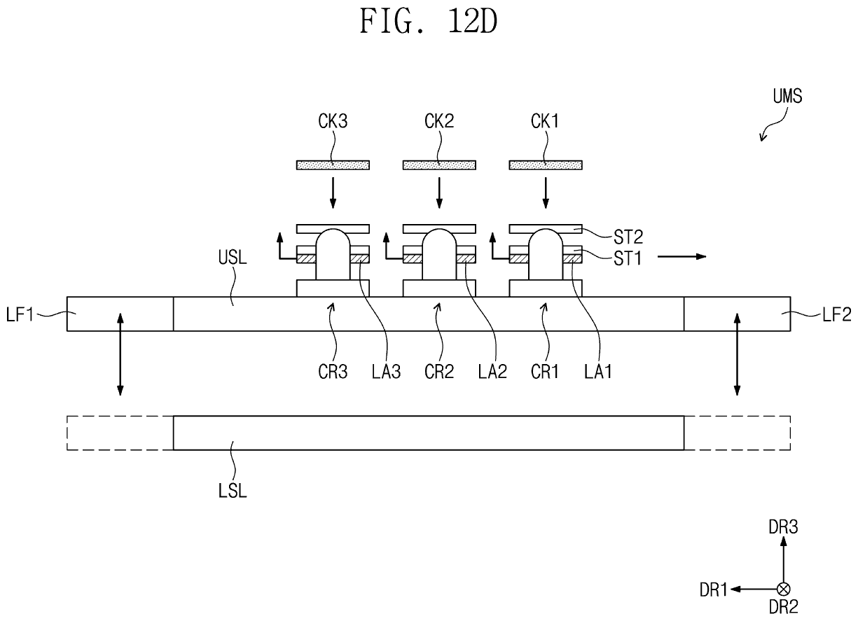

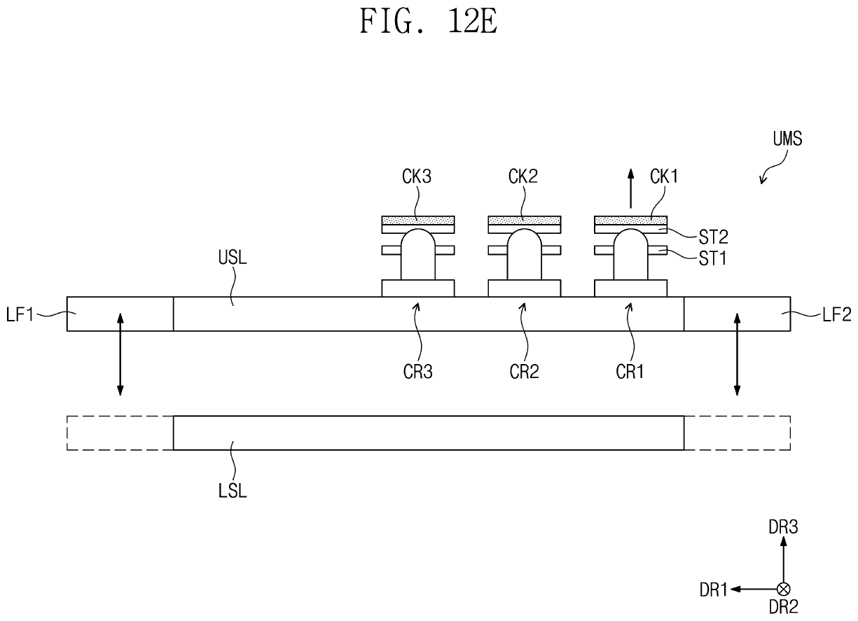

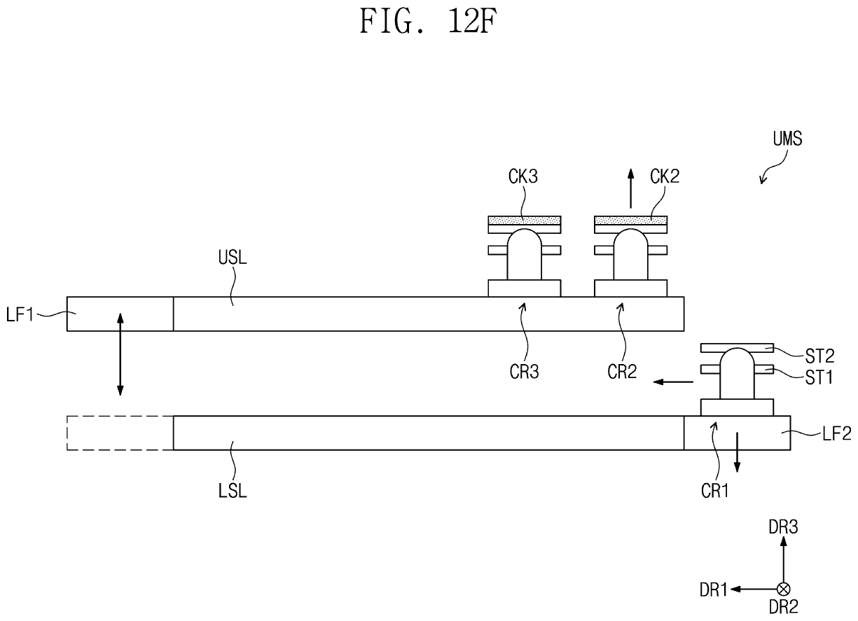

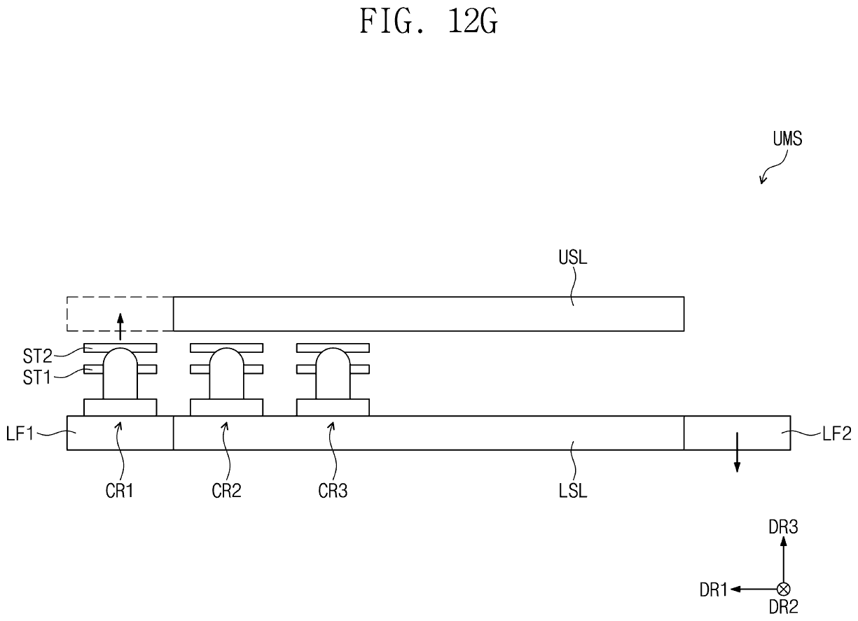

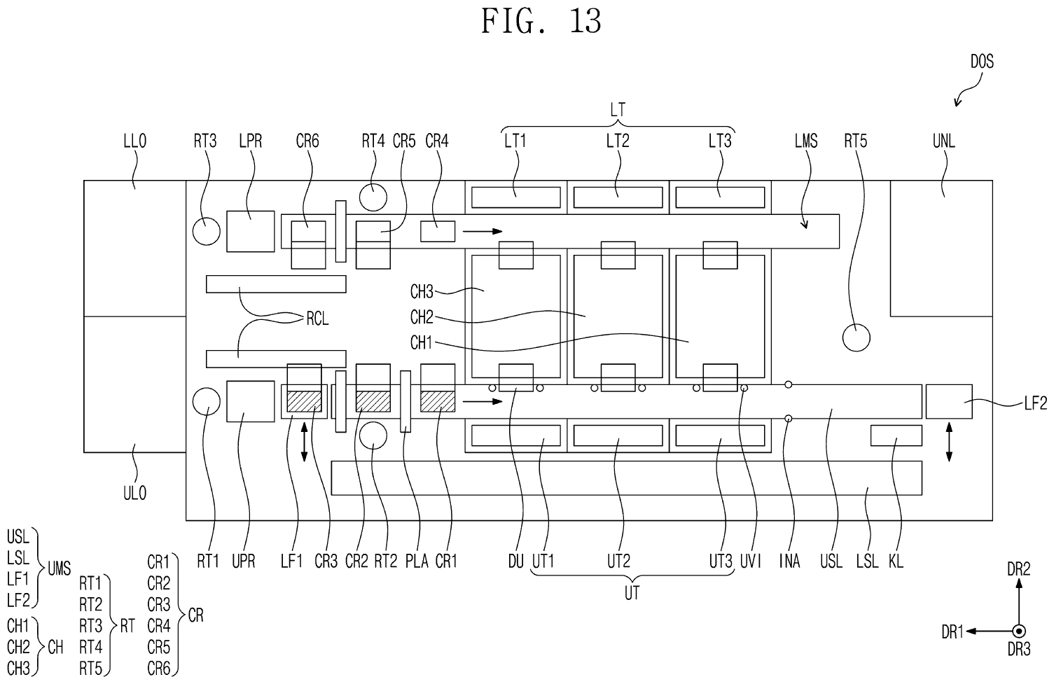

In the third operation mode, a protective film of the first material may be peeled off. Then, the third operation mode is switched to the second operation mode, and the first material from which the protective film is peeled off may face a ground. Accordingly, a foreign substance may be prevented from falling on the first material from which the protective film is peeled off, and a surface quality of the first material may be improved. This will be described in detail with reference to FIGS. 12A to 12G.

The connection module CC may be disposed between the first stage ST1 and the second stage ST2 in the third direction DR3. The connection module CC may be combined with the first stage ST1 and the second stage ST2 to allow the first and second stages ST1 and ST2 to rotate with respect to the rotation axis corresponding to the second direction DR2. That is, the first and second stages ST1 and ST2 facing each other may rotate in a clockwise direction or counterclockwise direction with respect to the second direction DR2 by the connection module CC.

The connection module CC may include a position control part ZP and a rotation part TC. The position control part ZP may protrude in the second direction DR2. The position control part ZP may control relative positions of the docking station DU and the carrier CR. That is, the position control part ZP may control the relative positions of the docking station DU and the carrier CR to allow the docking station DU to be combined with the carrier CR at a correct position. As the position control part ZP, a zero point clamping system may be used. The position control part ZP may be shaped like a cross and may have a stud protruding at an end thereof, however, the shape of the position control part ZP should not be limited thereto or thereby.

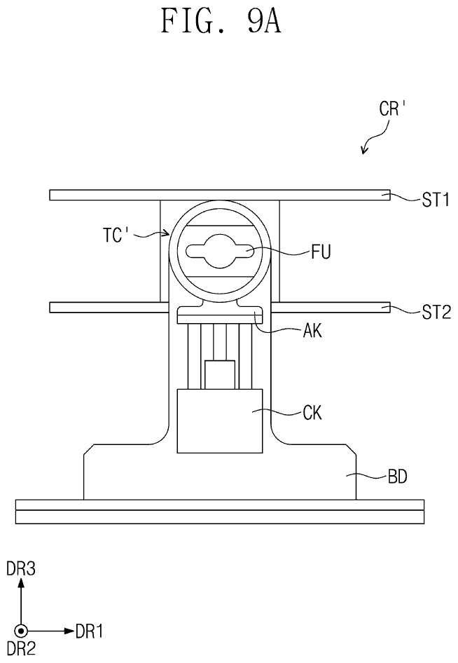

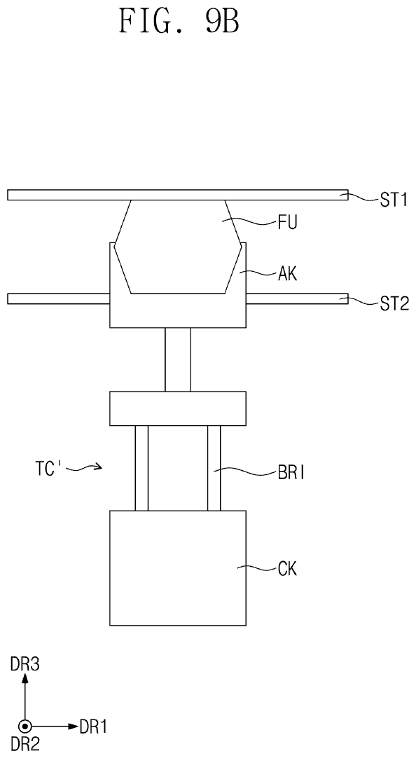

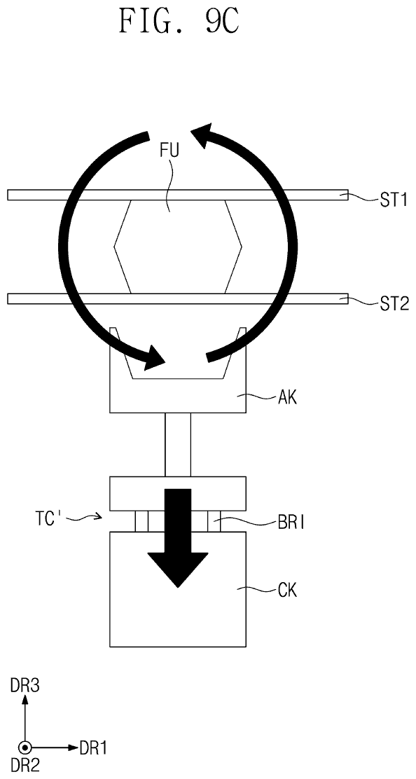

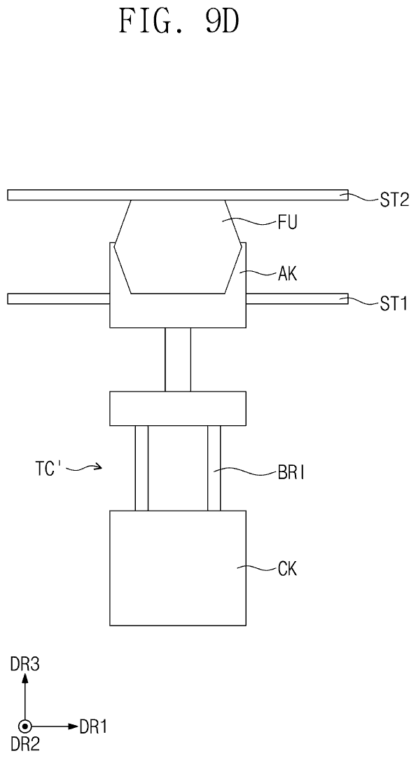

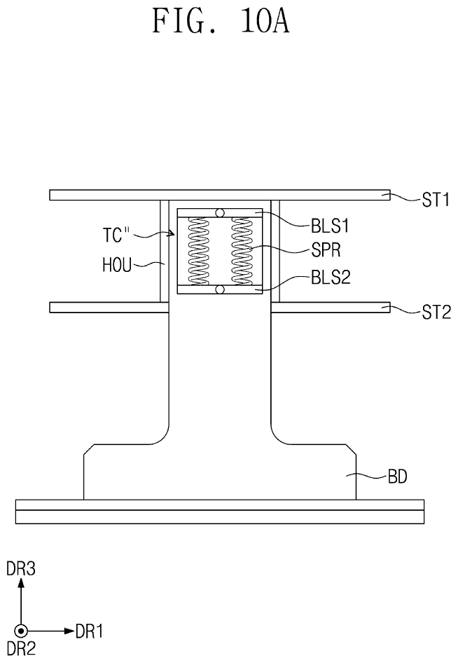

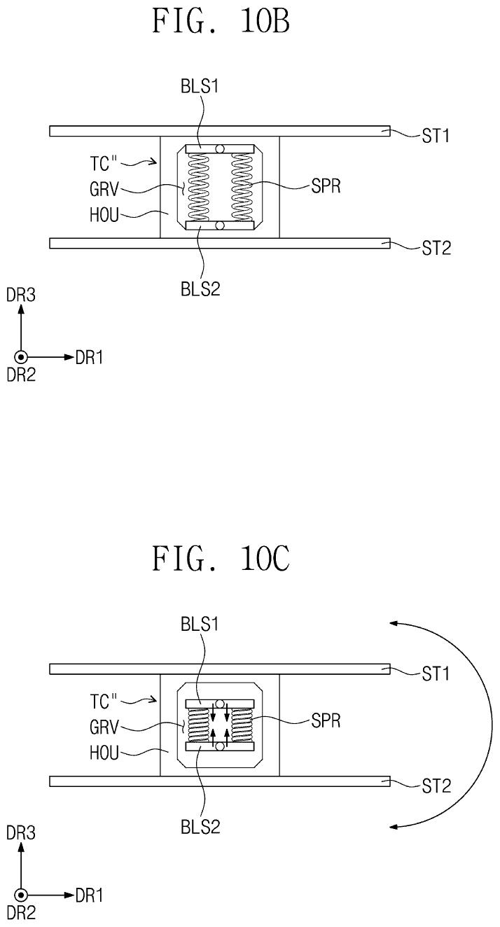

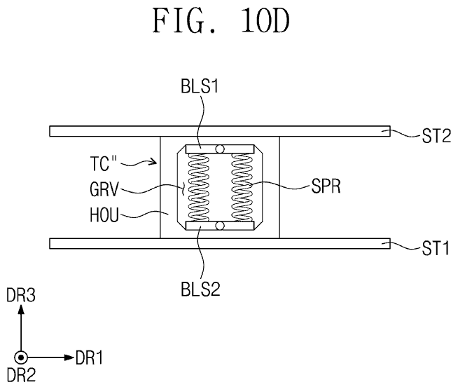

The rotation part TC may be combined with the first stage ST1 and the second stage ST2 to rotate the first stage ST1 and the second stage ST2. The rotation part TC may be a turn clamp that rotates when a certain pressure is applied thereto and does not rotate when the pressure is released. As an example, a spring may be placed inside the rotation part TC to hold a rotatable disk. When the docking station DU supplies air, the air may push the spring and the rotatable disk may rotate. That is, when the docking station DU supplies the air to the rotation part TC, the rotation part TC may rotate, and when the docking station DU stops supplying the air, the rotation part TC may not rotate. However, the structure of the rotation part TC should not be limited thereto or thereby and may be changed in various ways as long as the first stage ST1 and the second stage ST2 rotate. This will be described in detail with reference to FIGS. 9A to 10D.

The air inlet part AP may be combined with the body BD and may protrude in the second direction DR2. The air inlet part AP may be combined with the docking station DU and may act as an air inlet through which the air provided from the docking station DU flows. The air inlet part AP may have a bar shape provided with a passage through which the air passes and protruded in the second direction DR2. The air inlet part AP may be connected to the rotation part TC.

The check valve CV may be disposed in the connection module CC to maintain a vacuum state after connection between the docking station DU and the carrier CR is terminated. That is, the docking station DU may be combined with the carrier CR to form the vacuum state in a component of the carrier CR.

The check valve CV may allow the vacuum state to be maintained after connection between the docking station DU and the carrier CR is terminated. The check valve CV may be a valve that allows a fluid to flow only in one direction. The check valve CV may be any valve that maintains the vacuum state. An object to which the check valve CV is coupled may be changed. As an example, the check valve CV may be combined with the first stage ST1 and the second stage ST2. An inlet of the check valve CV may include an O-ring to prevent the outflow and inflow of the air.

The connection module TK may be connected between the check valve CV and the first and second stages ST1 and ST2. The connection module TK may transmit the suction force generated by the vacuum state formed by the docking station DU to the first stage ST1 and the second stage ST2. Accordingly, the first stage ST1 may suction-hold the first material, and the second stage ST2 may suction-hold the second material. The connection module TK may have a pipe shape through which an inner space is defined. The connection module TK may include a first connection module TK1 and a second connection module TK2. The first connection module TK1 and the second connection module TK2 may be connected to the check valve CV, and thus, the inner space of the first and second connection modules TK1 and TK2 may be maintained in the vacuum state.

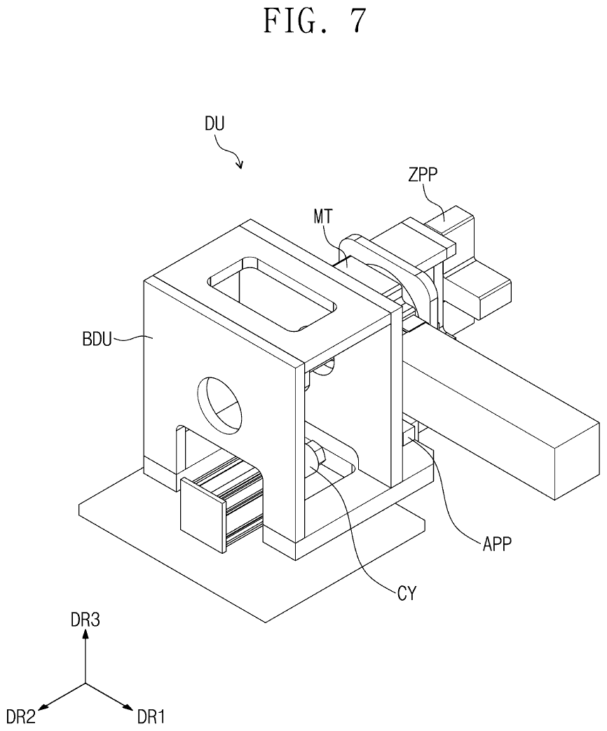

FIG. 7 is a perspective view of the docking station DU according to an embodiment of the present disclosure.

Referring to FIGS. 4 and 7, the docking station DU may be detachably combined with the carrier CR. The docking station DU may be combined with the carrier CR to supply the air or power to the carrier CR or to form the vacuum state that provides the suction force to the carrier CR. The docking station DU may include a docking body BDU, a power supply part MT, a cylinder CY, a first connection part ZPP, and a second connection part APP.

The docking station DU or the carrier CR may reciprocate in the second direction DR2. As an example, the docking station DU may move in a direction opposite to the second direction DR2 to be combined with the carrier CR. The docking station DU may move in the second direction DR2 to be released from its connection with the carrier CR. As described later, when the carrier CR moves in the first direction DR1, the coupling between the docking station DU and the carrier CR may be released. Since the vacuum state is formed in one component of the carrier CR by the power of the docking station DU and the vacuum state is maintained by the check valve CV, the vacuum state may be maintained even though a separate vacuum valve is not connected to the carrier CR.

The docking body BDU may have a box shape in which an inner space is defined. The power supply part MT and the cylinder CY may be disposed in the docking body BDU. However, the shape of the docking body BDU should not be limited thereto or thereby and may be changed in various ways.

The power supply part MT may provide the power to the carrier CR when the docking station DU is combined with the carrier CR. The rotation part TC of the carrier CR may rotate by the power provided from the power supply part MT. The vacuum state may be formed in one component of the carrier CR by the power provided from the power supply part MT. The power supply part MT may include a motor and a vacuum pump. Components of the power supply part MT should not be limited thereto or thereby and may include various general-purpose components.

The power supply part MT may be combined with the first connection part ZPP. The first connection part ZPP may protrude in the direction opposite to the second direction DR2. The first connection part ZPP may have a shape corresponding to the position control part ZP. When the docking station DU is combined with the carrier CR, the first connection part ZPP may be combined with the position control part ZP. The power from the power supply part MT may be provided to the position control part ZP through the first connection part ZPP. The power provided to the position control part ZP may be transmitted to the rotation part TC to allow the rotation part TC to rotate in a rotation mode.

The vacuum state formed by the power provided from the power supply part MT may be transmitted to the check valve CV through the first connection part ZPP. The first connection part ZPP may be combined with the check valve CV, and thus, the power supply part MT may be connected to the connection module TK. In this case, the vacuum state formed by the power supply part MT may be provided to the first stage ST1 and the second stage ST2 through the connection module TK. This vacuum state may be maintained by the check valve CV even though connection between the docking station DU and the carrier CR is released.

The cylinder CY may supply the air to the carrier CR when the docking station DU is combined with the carrier CR. The fixing of the rotation part TC may be terminated by the air provided by the cylinder CY, and thus, a first rotation mode in which the rotation part TC rotates may be formed. When the cylinder CY stops supplying the air, the rotation part TC may be in a fixed mode in which the rotation part TC does not rotate.

The cylinder CY may be combined with the second connection part APP. The second connection part APP may protrude in the direction opposite to the second direction DR2. The second connection part APP may have a shape corresponding to the air inlet part AP. The second connection part APP may be combined with the air inlet part AP when the docking station DU is combined with the carrier CR. The second connection part APP may transmit the air provided from the docking station DU to the air inlet part AP and the rotation part TC. The cylinder CY may be implemented in various ways to supply the air.

FIGS. 8A to 8E are front views illustrating an operation of the transport unit according to an embodiment of the present disclosure.

Referring to FIGS. 8A and 8B, the docking station DU may move in the direction opposite to the second direction DR2. The docking station DU may be combined with the carrier CR. The first stage ST1 may be loaded with the first material BUD. The first connection part ZPP may be combined with the position control part ZP, and the second connection part APP may be combined with the air inlet part AP. In this case, the position control part ZP may control the relative positions between the docking station DU and the carrier CR to allow the docking station DU to be combined with the carrier CR at the correct position.

After the first connection part ZPP is combined with the position control part ZP, the power supply part MT of the docking station DU may form the vacuum state in one component of the carrier CR. The power supply part MT may include the vacuum pump, and the vacuum pump may allow the check valve CV and the connection module TK of the carrier CR to be in the vacuum state. After the second connection part APP is combined with the air inlet part AP, the cylinder CY may supply the air to the air inlet part AP. The supplied air may be provided to the rotation part TC connected to the air inlet part AP, and thus, the rotation part TC may be in the rotation mode.

Referring to FIG. 8C, when the first connection part ZPP is combined with the position control part ZP, the first stage ST1 and the second stage ST2 may rotate by the power provided from the power supply part MT. As the rotation part TC rotates, the first and second stages ST1 and ST2 combined with the rotation part TC may rotate. When the first stage ST1 rotates, the first material BUD loaded on the first stage ST1 may be arranged to be perpendicular to the ground. That is, the normal direction (e.g., the first direction DR1) of the first material BUD may be perpendicular to the ground direction (i.e., direction opposite to the third direction DR3). As described later with reference to FIGS. 12A to 12G, as a peeling-off process is performed after the first material BUD is positioned vertically to the ground, the peeled-off surface may be prevented from being contaminated by fallen foreign substances.

Referring to FIG. 8D, the first stage ST1 and the second stage ST2 may further rotate by the power provided from the power supply part MT. The first stage ST1 may rotate to face the ground. Accordingly, the first material BUD on which the peeling-off process is applied may face the ground. Therefore, the peeled-off surface may be prevented from being contaminated by the fallen foreign substances after the peeling-off process.

Referring to FIG. 8E, the first connection part ZPP and the position control part ZP may be separated from each other. The second connection part APP and the air inlet part AP may be separated from each other. Then, the docking station DU may move in the second direction DR2.

FIGS. 9A to 9D are side views of a carrier CR′ according to an embodiment of the present disclosure. In FIGS. 9A to 9D, a rotation part TC′ may have a different structure from that of the rotation part TC of FIG. 5.

Referring to FIG. 9A, the rotation part TC′ may include a one-way cylinder CK combined with a body BD, a fixing end AK, and a rotation housing FU. However, components of the rotation part TC′ should not be limited thereto or thereby and may further include various general-purpose components.

The one-way cylinder CK may be combined with the fixing end AK to allow the fixing end AK to reciprocate in the third direction DR3. When the fixing end AK moves in the third direction DR3 by the one-way cylinder CK, the rotation part TC′ may be in a fixed mode. When the fixing end AK moves in a direction opposite to the third direction DR3 by the one-way cylinder CK, the rotation part TC′ may be in a rotation mode.

The fixing end AK may have a shape corresponding to the rotation housing FU. The fixing end AK may be inserted into and combined with the rotation housing FU.

The rotation housing FU may be combined with a first stage ST1 and a second stage ST2. The rotation housing FU may be disposed between the first stage ST1 and the second stage ST2. The rotation housing FU may be inserted into and combined with the fixing end AK to prevent the first stage ST1 and the second stage ST2 from rotating further. The rotation housing FU may have various shapes depending on a rotation angle required by the first stage ST1 and the second stage ST2.

Referring to FIG. 9B, the one-way cylinder CK may push the fixing end AK combined with a bridge BRI to the third direction DR3. Accordingly, the rotation housing FU with an angled shape may be inserted into and combined with the fixing end AK, and thus, the rotation of the rotation housing FU is no longer possible. Therefore, the first stage ST1 and the second stage ST2 combined with the rotation housing FU may not rotate further.

Referring to FIG. 9C, the one-way cylinder CK may pull the bridge BRI in the direction opposite to the third direction DR3 to release connection between the fixing end AK and the rotation housing FU. Therefore, there is no restriction on the rotation of the rotation housing FU, and thus, the rotation part TC′ may be in the rotation mode. In this case, the first stage ST1 and the second stage ST2 may rotate with respect to a rotation axis extending in the second direction DR2.

Referring to FIG. 9D, the one-way cylinder CK may push the bridge BRI to the third direction DR3 to allow the fixing end AK to be combined with the rotation housing FU. The rotation housing FU may rotate to correspond to the shape of the fixing end AK and may be combined with the fixing end AK. The rotation housing FU may be blocked by the fixing end AK and may not rotate further, and rotation part TC′ may be in the fixed mode. As shown in FIG. 9D, the rotation housing FU may be fixed after the rotation housing FU rotates to allow the first stage ST1 to face the ground and the second stage ST2 to face upward.

FIGS. 10A to 10D are side views of a carrier according to an embodiment of the present disclosure. In FIGS. 10A to 10D, a rotation part TC″ may have a different structure from that of the rotation part TC of FIG. 5.

Referring to FIG. 10A, the rotation part TC″ may include a first fixing member BLS1, a second fixing member BLS2, a rotation housing HOU, and a spring SPR. However, components of the rotation part TC″ should not be limited thereto or thereby and may further include various general-purpose components.

The first fixing member BLS1 and the second fixing member BLS2 may be arranged to face each other. The first fixing member BLS1 may have a shape corresponding to a shape of the second fixing member BLS2. The first fixing member BLS1 and the second fixing member BLS2 may be combined with each other by a spring SPR disposed between the first fixing member BLS1 and the second fixing member BLS2.

The rotation housing HOU may be disposed between a first stage ST1 and a second stage ST2 and may combine the first stage ST1 with the second stage ST2. When the rotation housing HOU rotates, the first stage ST1 and the second stage ST2 may also rotate.

Referring to FIG. 10B, a fixing groove GRV may be defined in the rotation housing HOU. The first fixing member BLS1 and the second fixing member BLS2 may be placed in the fixing groove GRV. When a docking station (refer to DU of FIG. 7) does not provide a power, the first fixing member BLS1 and the second fixing member BLS2 may push each other by the tension of the spring SPR. Accordingly, the first fixing member BLS1 and the second fixing member BLS2 may be in contact with one side and an opposite side of the fixing groove GRV, respectively. The one side of the fixing groove GRV may have a shape corresponding to the first fixing member BLS1, and the opposite side of the fixing groove GRV may have a shape corresponding to the second fixing member BLS2. In this case, when the rotation housing HOU attempts to rotate, the first fixing member BLS1 and the second fixing member BLS2 may be blocked by the fixing groove GRV and may not rotate. The rotation part TC″ may be in a fixed mode.

Referring to FIG. 10C, when the power is provided by the docking station DU (refer to FIG. 7), the first fixing member BLS1 and the second fixing member BLS2 may become close to each other. In this case, the first fixing member BLS1 and the second fixing member BLS2 may move away from the one side and the opposite side of the fixing groove GRV, respectively. Thus, even though the rotation housing HOU rotates, the first fixing member BLS1 and the second fixing member BLS2 may not interfere with the fixing groove GRV. Accordingly, the rotation housing HOU may rotate, and thus, the first stage ST1 and the second stage ST2 may also rotate. In this case, the rotation part TC″ may be in a rotation mode.

Referring to FIG. 10D, when the first stage ST1 and the second stage ST2 rotate to a desired position, the power from the docking station DU (refer to FIG. 7) may be blocked. Then, the first stage ST1 and the second stage ST2 may move away from each other by the tension of the spring SPR. The first stage ST1 may be in contact with the one side of the fixing groove GRV, and the second stage ST2 may be in contact with the opposite side of the fixing groove GRV. In this case, when the rotation housing HOU attempts to rotate, the first fixing member BLS1 and the second fixing member BLS2 may be blocked by the fixing groove GRV and may not rotate. The rotation part TC″ may be in the fixed mode.

FIG. 11 is a plan view of a lamination system DOS according to an embodiment of the present disclosure.

Referring to FIG. 11, the lamination system DOS may include a first loader ULO, a second loader LLO, a multi-joint robot RT, preliminary alignment units UPR and LPR, a cleaner RCL, a plasma processor PLA, a first line UMS, a second line LMS, the carrier CR, the docking station DU, a vision alignment unit UVI, a chamber CH, a first supply unit UT, a second supply unit LT, an inspection unit INA, and a unloader UNL. However, components of the lamination system DOS should not be limited thereto or thereby and may further include various general-purpose components.

The lamination system DOS may include two circular material handling systems, i.e., the first line UMS and the second line LMS. Each of the first line UMS and the second line LMS may not need to return to the first and second loaders ULO and LLO after moving the material to load the material to the chamber CH. Accordingly, the total process time for the lamination may be shortened. This will be described in detail with reference to FIGS. 12A to 12G.

The lamination system DOS may load the material, which is to be laminated, on the carrier CR and then may move the material to the chamber. When materials are laminated to each other in the chamber CH, the laminated materials may be loaded on the carrier CR again and may move to the unloader UNL. The laminated materials may be unloaded from the carrier CR by the unloader UNL. In the present embodiment, the carrier CR and the docking station DU may be the carrier CR and the docking station DU described with reference to FIGS. 4 to 7.

The first line UMS and the second line LMS may extend in the first direction DR1. The chamber CH may be disposed between the first line UMS and the second line LMS. One or more carriers CR1, CR2, and CR3 each on which the first material is loaded may reciprocate along the first line UMS in the first direction DR1. One or more carriers CR4, CR5, and CR6 each on which the second material is loaded may reciprocate along the second line LMS in the first direction DR1.

First to sixth carriers CR1 to CR6 may be rotatable and may include two stages facing each other.

The first loader ULO and the second loader LLO may load the materials provided into the lamination system DOS from the outside of the lamination system DOS. The first loader ULO may move the first materials placed on a tray to a position where a second multi-joint robot RT2 is able to pick up the first materials. The second loader LLO may move the second materials placed on a tray to a position where a fourth multi-joint robot RT4 is able to pick up the second materials.

A first multi-joint robot RT1 (or a first loading module) may load the first materials on the first, second, and third carriers CR1, CR2, and CR3 arranged in the first line UMS, respectively. The third multi-joint robot RT3 (or a second loading module) may load the second materials on the fourth, fifth, and sixth carriers CR4, CR5, and CR6 arranged in the second line LMS, respectively. However, the first to sixth carriers CR1 to CR6 are merely examples of the carrier CR, and the number of the carriers CR may be changed.

The preliminary alignment units UPR and LPR may include a first preliminary alignment unit UPR and a second preliminary alignment unit LPR. The first preliminary alignment unit UPR may be disposed adjacent to the first line UMS. The first preliminary alignment unit UPR may allow the first material to be placed into correct positions after being loaded on the first, second, and third carriers CR1, CR2, and CR3. The first preliminary alignment unit UPR may allow the first materials to be aligned with an X-axis or Y-axis on the first, second, and third carriers CR1, CR2, and CR3.

The second preliminary alignment unit LPR may be disposed adjacent to the second line LMS. The second preliminary alignment unit LPR may allow the second material to be placed into correct positions after being loaded on the fourth, fifth, and sixth carriers CR4, CR5, and CR6. The second preliminary alignment unit LPR may allow the second material to be aligned with the X-axis or Y-axis on the fourth, fifth, and sixth carriers CR4, CR5, and CR6.

The first, second, and third carriers CR1, CR2, and CR3 may carry the first materials loaded thereon to the direction opposite to the first direction DR1 on the first line UMS. The fourth, fifth, and sixth carriers CR4, CR5, and CR6 may carry the second materials loaded thereon to the direction opposite to the first direction DR1 on the second line LMS. The first, second, and third carriers CR1, CR2, and CR3 may carry the first materials respectively loaded thereon to the chamber CH. The fourth, fifth, and sixth carriers CR4, CR5, and CR6 may carry the second materials respectively loaded thereon to the chamber CH. The first materials and the second materials, which moved into the chamber CH, may be laminated to each other.

As an example, the first carrier CR1 may carry the first material to the first chamber CH1, the second carrier CR2 may carry the first material to the second chamber CH2, and the third carrier CR3 may carry the first material to the third chamber CH3. The fourth carrier CR4 may carry the second material to the first chamber CH1, the fifth carrier CR5 may carry the second material to the second chamber CH2, and the sixth carrier CR6 may carry the second material to the third chamber CH3. In the first, second, and third chambers CH1, CH2, and CH3, the first material and the second material, which are transmitted to each of the first, second, and third chambers CH1, CH2, and CH3, may be laminated to each other in the first, second, and third chambers CH1, CH2, and CH3.

The docking station DU may be provided in plural, and the docking stations DU may be arranged along the first line UMS and the second line LMS. The first, second, and third carriers CR1, CR2, and CR3 may be combined with the docking stations DU arranged on the first line UMS. The docking stations DU may provide the suction force to the first, second, and third carriers CR1, CR2, and CR3, and the first, second, and third carriers CR1, CR2, and CR3 may suction-hold the first material using the suction force. The first, second, and third carriers CR1, CR2, and CR3 may move when the first, second, and third carriers CR1, CR2, and CR3 are detached from the docking stations DU.

The fourth, fifth, and sixth carriers CR4, CR5, and CR6 may be combined with the docking stations DU arranged on the second line LMS. The docking station DU may provide the suction force to the fourth, fifth, and sixth carriers CR4, CR5, and CR6, and the fourth, fifth, and sixth carriers CR4, CR5, and CR6 may suction-hold the second material using the suction force. The fourth, fifth, and sixth carriers CR4, CR5, and CR6 may move when the fourth, fifth, and sixth carriers CR4, CR5, and CR6 are detached from the docking stations DU.

The cleaner RCL may be disposed adjacent to the first line UMS and the second line LMS. The cleaner RCL may clean the first material and the second material loaded on the first to sixth carriers CR1 to CR6. As an example, the cleaner RCL may remove foreign substances from a surface of the first material and the second material.

The second multi-joint robot RT2 may be disposed adjacent to the first line UMS. The second multi-joint robot RT2 may peel off a protective film of the first material loaded on each of the first, second, and third carriers CR1, CR2, and CR3. The peeling-off of the protective film may be similar to removing one of two release papers attached to both sides of an adhesive tape.

A fourth multi-joint robot RT4 may be disposed adjacent to the second line LMS. The fourth multi-joint robot RT4 may peel off a protective film of the second material loaded on each of the fourth, fifth, and sixth carriers CR4, CR5, and CR6. When the protective film is peeled off, the stages of the first to sixth carriers CR1 to CR6, which are provided with the first and second materials loaded thereon, may be arranged in a direction perpendicular to the ground. Accordingly, the peeled-off surface may be prevented from being contaminated by the fallen foreign substances. This will be described in detail with reference to FIG. 12B.

The peeled-off surface of at least one of the first material and the second material may be plasma-treated by the plasma processor PLA.

The carrier CR may move in the direction opposite to the first direction DR1 and may be disposed adjacent to a corresponding chamber CH. The first supply unit UT may be disposed adjacent to the first line UMS, and the second supply unit LT may be disposed adjacent to the second line LMS.

The first supply unit UT may supply the first materials loaded on the first, second, and third carriers CR1, CR2, and CR3 to the first, second, and third chambers CH1, CH2, and CH3, respectively. The second supply unit LT may supply the second materials loaded on the fourth, fifth, and sixth carriers CR4, CR5, and CR6 to the first, second, and third chambers CH1, CH2, and CH3, respectively.

The vision alignment unit UVI may accurately align the materials input into the chamber CH. The vision alignment unit UVI may detect alignment marks located on the materials to calculate positional errors of the materials through image processing. Based on the data obtained through the above image processing, the materials to be input into the chamber CH may be accurately aligned.

A laminate obtained by laminating the materials in the chamber CH may be loaded on a corresponding carrier among the first, second, and third carriers CR1, CR2, and CR3. The first, second, and third carriers CR1, CR2, and CR3 may carry the laminate loaded thereon to the direction opposite to the first direction DR1. The carried laminate may be inspected by the inspection unit INA to determine whether the laminate is defective. The laminate may be inverted by an inverter KL after passing through the inspection unit INA and then may be unloaded onto the unloader UNL by a fifth multi-joint robot RT5. In addition, the laminate may be unloaded onto the unloader UNL by the fifth multi-joint robot RT5 after passing through the inspection unit INA and then may be inverted by the inverter KL.

FIGS. 12A to 12G are side views of an operation of the first line according to an embodiment of the present disclosure.

Referring to FIG. 12A, the first line UMS may include a first-first line USL, a first-second line LSL, a first lift LF1, and a second lift LF2. The first-first line USL and the first-second line LSL may be arranged to face each other in an up-and-down direction. The first-first line USL may move in the direction opposite to the first direction DR1. The first-second line LSL may move in the first direction DR1. Each of the first lift LF1 and the second lift LF2 may reciprocate between the first-first line USL and the first-second line LSL. Hereinafter, the first line UMS will be mainly described, and descriptions on the first line UMS may be applied to the second line LMS. That is, the second line LMS may include a second-first line, a second-second line, and a lift reciprocating between the second-first line and the second-second line. Since details of the second line are the same as or similar to that of the first line, descriptions on the second line will be omitted.

The first, second, and third carriers CR1, CR2, and CR3 may be disposed on the first lift LF1 and the first-first line USL. A first-first material LA1, a first-second material LA2, and a first-third material LA3, which correspond to the first materials, may be loaded on the first, second, and third carriers CR1, CR2, and CR3, respectively. The first, second, and third carriers CR1, CR2, and CR3 may include the first stage ST1 and the second stage ST2. The first material may be loaded on the first stage ST1 of each of the first, second, and third carriers CR1, CR2, and CR3. In the present embodiment, the first, second, and third carriers CR1, CR2, and CR3 may be the carrier CR of FIG. 4.

Referring to FIG. 12B, the first stage ST1 and the second stage ST2 of the first carrier CR1 may rotate. The first stage ST1 and the second stage ST2 may rotate to allow the first stage ST1 to face a left side and the second stage ST2 to face a right side. In this case, the first carrier CR1 may be combined with the docking station DU (refer to FIG. 11) and the first stage ST1 and the second stage ST2 may rotate due to the power provided from the docking station DU. The protective film may be peeled off from the first-first material LA1 by the second multi-joint robot RT2 (refer to FIG. 11) when the first-first material LA1 is arranged perpendicular to the ground. Accordingly, the peeling-off process may be easily performed, and the peeled-off surface may be prevented from being contaminated by the fallen foreign substances after the peeling-off process.

Referring to FIG. 12C, the first stage ST1 and the second stage ST2 of the first carrier CR1 may further rotate than that shown in FIG. 12B to allow the first stage ST1 to face the ground and the second stage ST2 to face upward. Since the first-first material LA1 loaded on the first stage ST1 faces the ground, the peeled-off surface may be prevented from being contaminated by the fallen foreign substances while moving. As previously described, the first-first material LA1 may be fixed to the first stage ST1 by the suction force provided from the docking station DU (refer to FIG. 11) without being separated from the first stage ST1. In the second carrier CR2, the first-second material LA2 may be peeled off after the first stage ST1 and the second stage ST2 rotate as the first carrier CR1 shown in FIG. 12B.

Referring to FIG. 12D, the first-first material LA1, the first-second material LA2, and the first-third material LA3, which are loaded on the first, second, and third carriers CR1, CR2, and CR3, may be input into the first chamber CH1 (refer to FIG. 11), the second chamber CH2 (refer to FIG. 11), and the third chamber CH3 (refer to FIG. 11), respectively. First, second, and third laminates CK1, CK2, and CK3 each being laminated in the chamber CH (refer to FIG. 11) may be loaded on the first, second, and third carriers CR1, CR2, and CR3, respectively. The first laminate CK1 may be loaded on the second stage ST2 of the first carrier CR1. The second laminate CK2 may be loaded on the second stage ST2 of the second carrier CR2. The third laminate CK3 may be loaded on the second stage ST2 of the third carrier CR3.

Referring to FIGS. 12E and 12F, the first laminate CK1 loaded on the first carrier CR1 may be unloaded by the unloader UNL (refer to FIG. 11). Then, the first carrier CR1 may move on the second lift LF2. The second carrier CR2 may move in the direction opposite to the third direction DR3. The second carrier CR2 may move to the first-second line LSL from the first-first line USL. The second laminate CK2 loaded on the second carrier CR2 may be unloaded through the same process as the first carrier CR1.

Referring to FIGS. 12F and 12G, the second carrier CR2 and the third carrier CR3 may also move to the first-second line LSL by the second lift LF2 through the same process as the first carrier CR1. The first, second, and third carriers CR1, CR2, and CR3 disposed on the first-second line LSL may move in the first direction DR1. The first carrier CR1 may be disposed on the first lift LF1. The first lift LF1 with the first carrier CR1 loaded thereon may move in the third direction DR3. That is, the first lift LF1 may move the first carrier CR1 to the first-first line USL from the first-second line LSL. Then, the second carrier CR2 and the third carrier CR3 may also move to the first-first line USL from the first-second line LSL through the same process.

As the circular material handling system described with reference to FIGS. 12A to 12G is used, the time required to load and unload the materials may be reduced, and the total process time may be reduced. That is, the process time may be reduced by reducing the return time required to load the material into the chamber and then to return to the loading location.

FIG. 13 is a plan view of a lamination system DOS according to an embodiment of the present disclosure. The lamination system DOS shown in FIG. 13 has substantially the same structure as that of the lamination system DOS shown in FIG. 11 except a first line UMS. Accordingly, in FIG. 13, the same reference numerals denote the same elements in FIG. 11, and details thereof will be omitted.

Referring to FIG. 13, the first line UMS may include a first-first line USL, a first-second line LSL, a first lift LF1, and a second lift LF2. The first-first line USL and the first-second line LSL may extend in the first direction DR1. The first-first line USL and the first-second line LSL may be arranged to face each other in a horizontal direction. The first lift LF1 may be disposed adjacent to a first loader ULO and may reciprocate along the second direction DR2 between the first-first line USL and the first-second line LSL. The second lift LF2 may be disposed adjacent to an unloader UNL and may reciprocate along the second direction DR2 between the first-first line USL and the first-second line LSL.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present invention shall be determined according to the attached claims.

What is claimed is:

1. A transport unit comprising:
a carrier configured to carry a first material and a second material, which are loaded thereon; and
a docking station, which is detachably combined with the carrier and supplies an air or power to the carrier to form a vacuum state and to provide a suction force to the carrier, the carrier comprising:
a first stage on which the first material is loaded;
a second stage provided with the second material, which is loaded thereon and faces the first stage;
a connection module combined between the first stage and the second stage to rotate the first and second stages with respect to a rotation axis between the first stage and the second stage; and
a check valve disposed in the connection module to maintain the vacuum state after connection between the docking station and the carrier is released.

2. The transport unit of claim 1, further comprising a connection module combined between the check value and the first and second stages,
wherein the connection module transmits the vacuum state to the first and second stages, and the first and second stages are configured to suction-hold the first and second materials, respectively.

3. The transport unit of claim 1, wherein the carrier comprises:
a first operation mode in which the first stage faces upward and the second stage faces downward;
a second operation mode in which the first stage faces downward and the second stage faces upward; and
a third operation mode in which the first and second stages face a horizontal direction.

4. The transport unit of claim 1, wherein the connection module comprises:
a position control part, which controls relative positions between the docking station and the carrier; and
a rotation part combined with the first and second stages to rotate the first and second stages.

5. The transport unit of claim 4, wherein the rotation part operates in a rotation mode in which the rotation part rotates when the docking station supplies the air and in a fixed mode in which the rotation part does not rotate when the docking station stops supplying the air.

6. The transport unit of claim 4, wherein the rotation part comprises:
a rotation housing combined with the first and second stages;
a fixing end having a shape corresponding to the rotation housing to be inserted into and combined with the rotation housing; and
a one-way cylinder combined with the fixing end to allow the fixing end to reciprocate in one direction.

7. The transport unit of claim 4, wherein the rotation part comprises:
a first fixing member;
a second fixing member opposite to the first fixing member and combined with the first fixing member by a spring; and
a rotation housing provided with a fixing groove defined therein to accommodate the first and second fixing members, and
the rotation part rotates when a distance between the first fixing member and second fixing member decreases by the docking station.

8. The transport unit of claim 1, wherein the docking station comprises:
a power supply part, which supplies the power to the carrier; and
a cylinder, which supplies the air to the carrier.

9. The transport unit of claim 1, wherein each of the first material and the second material is at least one of a window and a display panel.

10. A lamination system comprising:
a first line along which at least one first carrier provided with a first material loaded thereon reciprocates in a first direction;
a second line along which at least one second carrier provided with a second material loaded thereon reciprocates in the first direction;
a chamber in which the first material is laminated to the second material;
a first supply unit configured to supply the first material to the chamber; and
a second supply unit configured to supply the second material to the chamber,
wherein the first line comprises:
a first-first line, which moves only in the first direction;
a first-second line, which moves only in a direction opposite to the first direction; and
a first lift, which reciprocates between the first-first line and the first-second line.

11. The lamination system of claim 10, wherein the second line comprises:
a second-first line, which moves only in the first direction;
a second-second line, which moves only in the direction opposite to the first direction; and
a second lift, which reciprocates between the second-first line and the second-second line.

12. The lamination system of claim 10, wherein the chamber is disposed between the first line and the second line.

13. The lamination system of claim 10, wherein the first-first line and the first-second line are arranged to face each other in an up-and-down direction crossing the first direction.

14. The lamination system of claim 10, wherein the first-first line and the first-second line are arranged to face each other in a horizontal direction crossing the first direction.

15. The lamination system of claim 10, wherein the first carrier comprises:
a first stage on which the first material is loaded;
a second stage opposite to the first stage;
a connection module combined between the first stage and the second stage to rotate the first and second stages with respect to a rotation axis between the first stage and the second stage; and
a check valve disposed in the connection module to maintain a vacuum state.

16. The lamination system of claim 10, further comprising:
a first loading module configured to load the first material in the first carrier; and
a second loading module configured to load the second material in the second carrier.

17. The lamination system of claim 10, further comprising a multi-joint robot configured to peel off a protective film of the first material.

18. The lamination system of claim 17, wherein the first carrier comprises two stages facing each other and being rotatable, and the stages rotate so that normal directions of the stages are to be perpendicular to an up-and-down direction when the protective film is peeled off.

19. The lamination system of claim 17, wherein the first carrier comprises two stages facing each other and being rotatable, and a stage on which the peeled-off first material is loaded among the two stages rotates to face a downward direction while moving to the chamber after the protective film is peeled off.

20. The lamination system of claim 10, wherein the first carrier comprises two stages facing each other and being rotatable, and a laminate obtained by laminating the first material to the second material is loaded on one stage among the two stages while moving in the first direction.
